(19) United States
(12) Patent Application Publication
(10) Pub. No.: US 2022/0013486 A1
(43) Pub. Date: Jan. 13, 2022

(54) SEMICONDUCTOR COMPOSITE STRUCTURE, METHOD FOR MAKING THE SAME, AND SEMICONDUCTOR DEVICE HAVING THE SAME

(71) Applicant: Powertech Technology Inc., Hsinchu (TW)

(72) Inventors: Shih-Chang HUANG, Hsinchu (TW); Yu-Cheng LIU, Hsinchu (TW)

(73) Assignee: Powertech Technology Inc., Hsinchu (TW)

(21) Appl. No.: 17/149,835

(22) Filed: Jan. 15, 2021

(30) Foreign Application Priority Data
Jul. 8, 2020 (TW) 109123056

(51) Int. Cl. H01L 23/00

(52) U.S. Cl. CPC H01L 24/13; H01L 24/11; H01L 25/0657; H01L 2224/13564; H01L 2224/13018

(57) ABSTRACT

A semiconductor composite structure includes an electrically conductive bump, and a patterned bonding layer. The electrically conductive bump includes a body portion for being electrically connected to a metal layer of a semiconductor substrate, and a contact portion disposed on the body portion opposite to the metal layer. The patterned bonding layer is disposed on the contact portion opposite to the body portion, and includes an electrically conductive portion and a recess portion depressed relative to the electrically conductive portion. An etching selectivity ratio of the conductive portion relative to the contact portion is greater than 1. A method for making the semiconductor composite structure and a semiconductor device are also disclosed.

### CROSS-REFERENCE TO RELATED APPLICATION

This application claims priority of Taiwanese Invention Patent Application No. 109123056, filed on Jul. 8, 2020.

### FIELD

The disclosure relates to a semiconductor composite structure, and more particularly to a semiconductor composite structure, a method for making the same, and a semiconductor device having the same.

### BACKGROUND

Three-dimensional integrated circuits (3D ICs), which are manufactured by stacking semiconductor chips to significantly decrease bonding wires between transistors, are undergoing rapid development in the current semiconductor industry. The bonding between semiconductor chips or wafers plays a key role in 3D IC. As the design of integrated circuits becomes more complicated, a metal bump is commonly used for bonding and electrical connection between semiconductor chips. In particular, copper is often used to make the metal bump due to its excellent electrical conductivity, thermal conductivity, and electromigration resistance. In a wafer bonding process, a solder paste is initially applied on a top surface of a copper bump formed on a conductive circuit of a semiconductor chip, and then is subjected to a reflow treatment, so as to form a solder ball. Such copper bump of the semiconductor chip can be bonded to a copper bump of another semiconductor chip through the solder ball. However, since the top surface of a conventional copper bump is flat, the melt of the solder ball might be squeezed out from between two copper bumps in the bonding process, which might result in a short circuit, or a poor bonding among the solder ball and the copper bumps (i.e., a reduced bonding strength between the semiconductor chips) of the 3D IC. Therefore, the conventional semiconductor product might have a relatively poor reliability.

### SUMMARY

Therefore, an object of the disclosure is to provide a semiconductor composite structure for electrically connecting to a metal layer of a semiconductor substrate that can alleviate or eliminate at least one of the drawbacks of the prior art. A method for making the semiconductor composite structure and a semiconductor device including the semiconductor composite structure are also provided.

According to a first aspect of the disclosure, a semiconductor composite structure includes an electrically conductive bump and a patterned bonding layer. The electrically conductive bump includes a body portion for being electrically connected to the metal layer, and a contact portion disposed on the body portion opposite to the metal layer. The patterned bonding layer is disposed on the contact portion opposite to the body portion, and includes an electrically conductive portion and a recess portion depressed relative to the electrically conductive portion. An etching selectivity ratio of the electrically conductive portion relative to the contact portion is greater than 1.

According to a second aspect of the disclosure, a method for making the abovementioned semiconductor composite structure includes the steps of:

(a) forming the body portion on the metal layer of the semiconductor substrate;

(b) forming the contact portion on the body portion opposite to the metal layer so as to obtain the electrically conductive bump;

(c) forming an electrically conductive layer on the contact portion opposite to the body portion, the electrically conductive layer being made of a material different from that of the contact portion; and

(d) patterning the electrically conductive layer to form the patterned bonding layer on the contact portion.

According to a third aspect of the disclosure, a semiconductor device includes a first semiconductor chip, a second semiconductor chip, and a connecting unit. The first semiconductor chip includes a first metal layer. The second semiconductor chip includes a second metal layer. The connecting unit is disposed to electrically connect the first semiconductor chip to the second semiconductor chip, and includes the abovementioned semiconductor composite structure and a solder layer. The body portion of the semiconductor composite structure is in electrical contact with the first metal layer. The solder layer is electrically connected between the second metal layer and the patterned bonding layer of the semiconductor composite structure.

### BRIEF DESCRIPTION OF THE DRAWINGS

Other features and advantages of the disclosure will become apparent in the following detailed description of the embodiments with reference to the accompanying drawings, of which:

FIG. 1 is a schematic view illustrating an embodiment of a semiconductor composite structure for electrically connecting to a metal layer of a semiconductor substrate according to the disclosure;

FIG. 2 is a schematic top view illustrating a patterned bonding layer of the embodiment;

FIGS. 3 to 5 are schematic top views respectively illustrating variations of the patterned bonding layer;

FIG. 6 is a flow chart illustrating consecutive steps of a method for making the semiconductor composite structure; and

FIG. 7 is a schematic view illustrating a semiconductor device having the semiconductor composite structure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

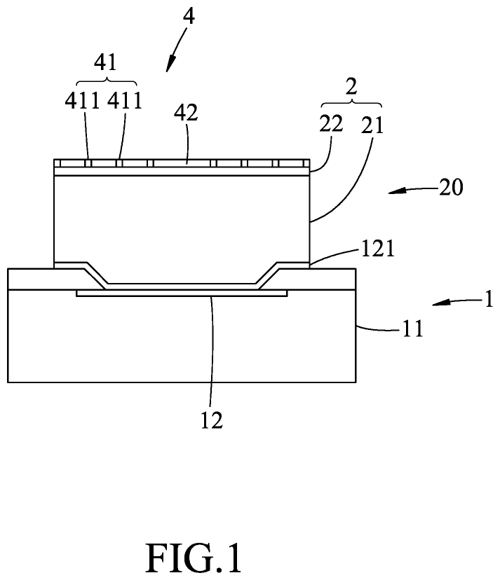

Referring to FIG. 1, an embodiment of a semiconductor composite structure 20 for electrically connecting to a metal layer 121 of a semiconductor substrate 1 is shown to include an electrically conductive bump 2 and a patterned bonding layer 4.

The semiconductor substrate 1 includes a substrate 11 and a conductive circuit 12. The metal layer 121 is a surface portion of the conductive circuit 12 exposed on the semiconductor substrate 1, and is used for external electrical connection.

The electrically conductive bump 2 includes a body portion 21 and a contact portion 22.

The body portion 21 is provided for being disposed on and electrically connected to the metal layer 121. In certain embodiments, the body portion 21 may be made of a material selected from the group consisting of Cu, Ni, Mo, W, Au, Pd, Ir, TiPd alloy, TiW alloy, and combinations thereof.

The contact portion 22 is disposed on the body portion 21 opposite to the metal layer 121. In certain embodiments, the contact portion 22 may be made of a material selected from the group consisting of Ni, Cu, Mo, W, Ti, Pd, Ta, Pt, nitrides thereof, and combinations thereof.

The patterned bonding layer 4 is disposed on the contact portion 22 opposite to the body portion 21, and includes an electrically conductive portion 41 and a recess portion 42 depressed relative to the electrically conductive portion 41. An etching selectivity ratio of the electrically conductive portion 41 relative to the contact portion 22 is greater than 1.

In certain embodiments, the electrically conductive portion 41 may have a thickness ranging from 1 μm to 5 μm.

In certain embodiments, the electrically conductive portion 41 may be made of a material selected from the group consisting of Cu, Ni, Mo, W, Au, Pd, Ir, TiPd alloy, TiW alloy, and combinations thereof.

In this embodiment, the body portion 21 is made of Cu, the contact portion 22 is made of Ni, and the electrically conductive portion 41 is made of Cu. It should be noted that although the body portion 21 and the electrically conductive portion 41 are made of the same material in this embodiment, they may be made of different materials in other embodiments.

There are no particular limitations on the configuration of the patterned bonding layer 4.

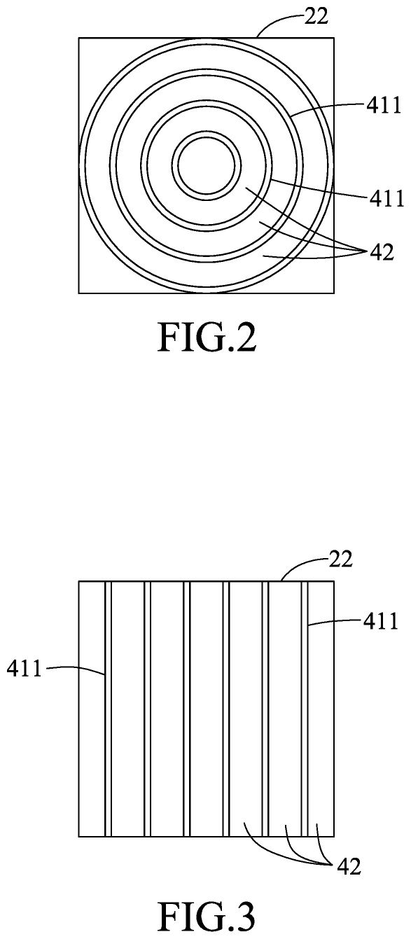

In an embodiment shown in FIG. 2, the patterned bonding layer 4 may include a plurality of the recess portions 42, and the electrically conductive portion 41 may have a plurality of concentric protrusions 411, which are coaxially disposed to permit the concentric protrusions 411 to alternate the recess portions 42. A cross-section of each of the protrusions 411 may have a rectangular shape or other geometric shapes.

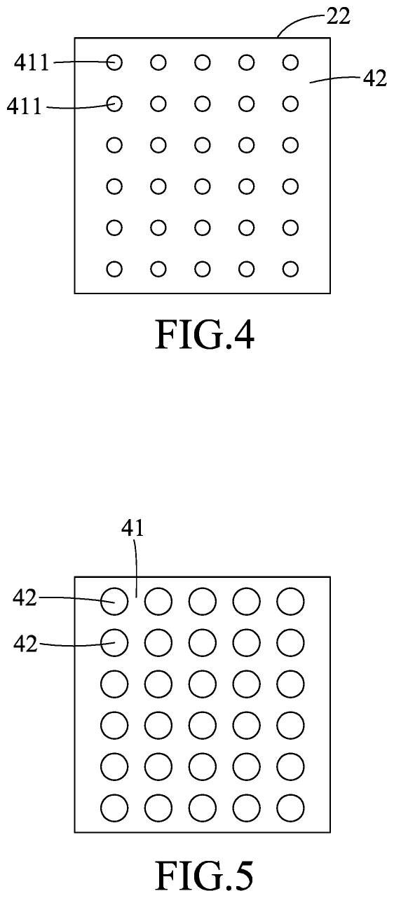

In an embodiment shown in FIG. 3, the patterned bonding layer 4 may include a plurality of the recess portions 42, and the electrically conductive portion 41 may have a plurality of protruding strips 411, which are disposed to alternate the recess portions 42 along a predetermined direction.

In an embodiment shown in FIG. 4, the electrically conductive portion 41 may include an array of protrusions 411, so as to define the recess portion 42 among the protrusions 411. In addition, to facilitate the flow of the solder (e.g., solder paste), two adjacent ones of the protrusions 411 may be spaced apart from each other by a spacing ranging from 8 μm to 40 μm. The spacing may be greater than the width of the protrusion 411.

In an embodiment shown in FIG. 5, the patterned bonding layer 4 may include a plurality of recess portions 42 spaced apart from each other by the electrically conductive portion 41.

Specifically, in the embodiments shown in FIGS. 2, 3 and 5, the recess portion 42 may have a width-to-depth ratio ranging from 1:2 to 1:5, which is conducive for directing solder to flow into the recess portion 42 and to be in close contact with the contact portion 22.

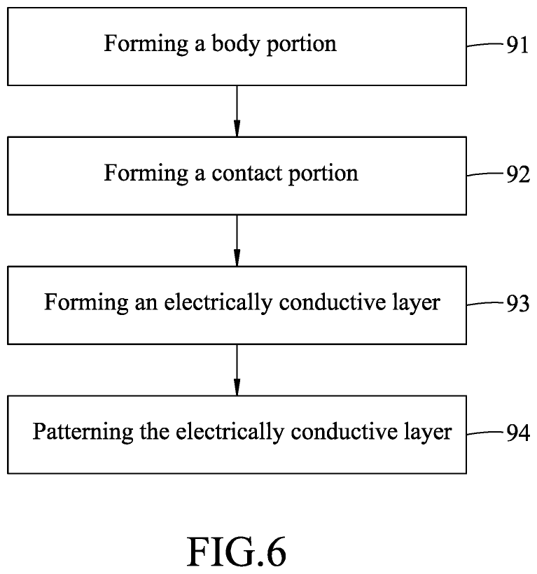

FIG. 6 illustrates a method for making the semiconductor composite structure 20 according to an embodiment of the disclosure. The method includes the following consecutive steps 91 to 94.

In step 91, the body portion 21 shown in FIG. 1 is formed on the metal layer 121 of the semiconductor substrate 1. To be specific, the body portion 21 may be deposited on the metal layer 121 of the semiconductor substrate 1 by physical vapor deposition (PVD), chemical vapor deposition (CVD), etc.

In step 92, the contact portion 22 shown in FIG. 1 is formed on the body portion 21 opposite to the metal layer 121, so as to obtain the electrically conductive bump 2. Specifically, the body portion 21 may be deposited on the body portion 21 opposite to the metal layer 121 by PVD, CVD, or the like.

In step 93, an electrically conductive layer (not shown) is formed on the contact portion 22 opposite to the body portion 21. Specifically, the electrically conductive layer may be deposited on the contact portion 22 opposite to the body portion 21 by PVD, CVD, or the like. In particular, the electrically conductive layer is made of a material different from that of the contact portion 22.

In step 94, the electrically conductive layer is patterned to form the patterned bonding layer 4 on the contact portion 22 (see FIG. 1).

In certain embodiments, step 94 may include sub-steps of: i) forming, on the electrically conductive layer, a mask layer which has a pattern corresponding to a desired pattern of the patterned bonding layer 4, ii) subjecting the electrically conductive layer to an etching process, and iii) removing the mask layer to obtain the patterned bonding layer 4 with the electrically conductive portion 41 and the recess portion 42. It is noted that the dimensions of the electrically conductive portion 41 and the recess portion(s) 42 can be controlled within a predetermined range by mask design and manufacturing process. In addition, by virtue of selecting a material of the contact portion 22, the contact portion 22 can have an etching resistance greater than that of the electrically conductive layer, so as to prevent excessive etching and different etching depths. Moreover, the height of the electrically conductive portion 41 and the depth of the recess portion(s) 42 may be controlled to be substantially the same as the thickness of the electrically conductive layer (not shown). Therefore, by using the mask layer, the patterned bonding layer 4 having a regular pattern may be easily obtained.

In other embodiments, to form the patterned bonding layer 4 shown in FIG. 4, step 93 may be implemented by forming the electrically conductive layer with a thickness ranging from 1 μm to 5 μm on the contact portion 22 using thin film deposition or spin coating, and step 94 may be implemented by subjecting the electrically conductive layer to an annealing treatment or a laser treatment, so as to obtain the array of protrusions 411. During the treatment in step 94, the array of protrusions 411 may be formed due to different surface tensions of the electrically conductive layer and the contact portion 22, and a cohesive force of the electrically conductive layer. In this case, the thickness of the electrically conductive layer may be greater than a width of the protrusion 411 to be formed and a spacing between two adjacent ones of the protrusions 411.

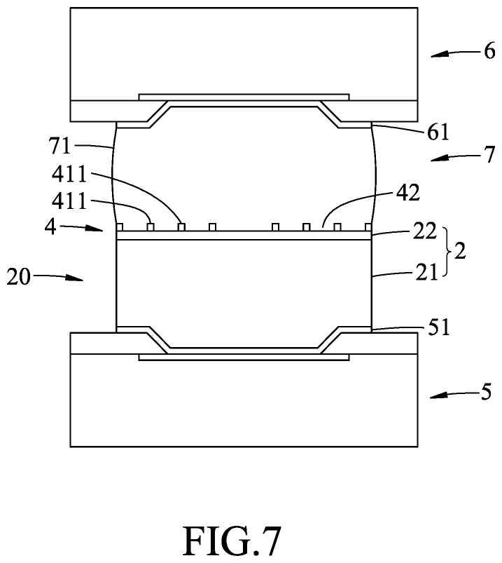

FIG. 7 illustrates a semiconductor device according to an embodiment of the disclosure. The semiconductor device includes a first semiconductor chip 5, a second semiconductor chip 6, and a connecting unit 7.

The first semiconductor chip 5 includes a conductive circuit with a first metal layer 51 which is disposed on a side of the first semiconductor chip 5, and which is exposed from a via of the first semiconductor chip 5 for external electrical connection. Similarly, the second semiconductor chip 6 includes a conductive circuit with a second metal layer 61 which is disposed on a side of the second semiconductor chip 6, and which is exposed from a via of the second semiconductor chip 6 for external electrical connection.

The connecting unit 7 is disposed to electrically connect the first semiconductor chip 5 to the second semiconductor chip 6, and includes the above-mentioned semiconductor composite structure 20 and a solder layer 71.

The body portion 21 of the semiconductor composite structure 20 is in electrical contact with the first metal layer 51. The solder layer 71 is interposed and electrically connected between the second metal layer 61 of the second semiconductor chip 6 and the patterned bonding layer 4 of the semiconductor composite structure 20, so as to electrically connect the first semiconductor chip 5 to the second semiconductor chip 6.

In certain embodiments, the solder layer 71 may be made of a solder paste material including a solder and an additive. The additive may be selected from the group consisting of Ag, Cu, Zn, Sb, Bi, and combinations thereof.

By virtue of the patterned bonding layer 4 of the semiconductor composite structure 20, a contact surface area between the solder layer 71 and the semiconductor composite structure 20 is increased, and thus a stronger bonding therebetween may be achieved, and the solder layer 71, which is melted in a reflow process, is less likely to be squeezed out from between the second metal layer 6 and the patterned bonding layer 4 in a bonding process.

In a process for making the semiconductor device, the semiconductor composite structure 20 is formed on a metal contact (i.e., the first metal layer 51) of the first semiconductor chip 5, and thereafter, the first semiconductor chip 5 is bonded to the second semiconductor chip 6 through the semiconductor composite structure 20 and the solder layer 71 (such as a solder paste).

In summary, with the provision of the semiconductor composite structure 20 for bonding the first and second semiconductor chips 5, 6, a part of solder in the solder layer 71 can flow into the recess portion(s) 42 during the bonding process, so as to increase the contact area and enhance the adhesion between the solder layer 71 and the semiconductor composite structure 20. In addition, the solder layer 71, which is melted in the reflow process, is less likely to be squeezed out during the bonding process. Moreover, since the dimensions of the electrically conductive portion 41 and the recess portion(s) 42 can be easily controlled, the solder layer 71, when melted, can be promoted to flow into the recess portion(s) 42. Therefore, formation of voids in the solder layer 71 can be avoided, so that the semiconductor device of this disclosure can have desired reliability and other physical properties.

In the description above, for the purposes of explanation, numerous specific details have been set forth in order to provide a thorough understanding of the embodiment. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiment, it is understood that this disclosure is not limited to the disclosed embodiment but is intended to cover various arrangements included within the spirit and scope of the broadest interpretation so as to encompass all such modifications and equivalent arrangements.

What is claimed is:

1. A semiconductor composite structure for electrically connecting to a metal layer of a semiconductor substrate, said semiconductor composite structure comprising:
an electrically conductive bump including a body portion for being electrically connected to the metal layer, and a contact portion disposed on said body portion opposite to the metal layer; and
a patterned bonding layer which is disposed on said contact portion opposite to said body portion, and which includes an electrically conductive portion and a recess portion depressed relative to said electrically conductive portion,
wherein an etching selectivity ratio of said electrically conductive portion relative to said contact portion is greater than 1.

2. The semiconductor composite structure of claim 1, wherein said recess portion has a width-to-depth ratio ranging from 1:2 to 1:5.

3. The semiconductor composite structure of claim 2, wherein said patterned bonding layer includes a plurality of said recess portions, and said electrically conductive portion has a plurality of concentric protrusions, which are coaxially disposed to permit said concentric protrusions to alternate said recess portions.

4. The semiconductor composite structure of claim 2, wherein said patterned bonding layer includes a plurality of said recess portions, and said electrically conductive portion has a plurality of protruding strips, which are disposed to alternate said recess portions along a predetermined direction.

5. The semiconductor composite structure of claim 2, wherein said electrically conductive portion includes an array of protrusions, so as to define said recess portion among said protrusions.

6. The semiconductor composite structure of claim 5, wherein two adjacent ones of said protrusions are spaced apart from each other by a spacing ranging from 8 μm to 40 μm.

7. The semiconductor composite structure of claim 1, wherein said patterned bonding layer includes a plurality of said recess portions spaced apart from each other by said electrically conductive portion.

8. The semiconductor composite structure of claim 1, wherein said electrically conductive portion has a thickness ranging from 1 μm to 5 μm.

9. The semiconductor composite structure of claim 1, wherein said contact portion is made of a material selected from the group consisting of Ni, Cu, Mo, W, Ti, Pd, Ta, Pt, nitrides thereof, and combinations thereof.

10. The semiconductor composite structure of claim 1, wherein said body portion and said electrically conductive portion are made of the same or different materials, and are independently made of a material selected from the group consisting of Cu, Ni, Mo, W, Au, Pd, Ir, TiPd alloy, TiW alloy, and combinations thereof.

11. A method for making a semiconductor composite structure as claimed in claim 1, comprising the steps of:
forming the body portion on the metal layer of the semiconductor substrate;
forming the contact portion on the body portion opposite to the metal layer so as to obtain the electrically conductive bump;
forming an electrically conductive layer on the contact portion opposite to the body portion, the electrically conductive layer being made of a material different from that of the contact portion; and
patterning the electrically conductive layer to form the patterned bonding layer on the contact portion.

12. A semiconductor device comprising:
a first semiconductor chip including a first metal layer;
a second semiconductor chip including a second metal layer; and
a connecting unit disposed to electrically connect said first semiconductor chip to said second semiconductor chip, and including
a semiconductor composite structure as claimed in claim 1, said body portion of said semiconductor composite structure being in electrical contact with said first metal layer, and
a solder layer electrically connected between said second metal layer and said patterned bonding layer of said semiconductor composite structure.
